(19) United States
(12) Patent Application Publication
(10) Pub. No.: US 2022/0069179 A1
(43) Pub. Date: Mar. 3, 2022

(54) LIGHT SOURCE MODULE

(71) Applicant: Primax Electronics Ltd., Taipei (TW)

(72) Inventors: Ya-Chin Tu, Taipei (TW); Hung-Wei Kuo, Taipei (TW)

(21) Appl. No.: 17/108,857

(22) Filed: Dec. 1, 2020

Related U.S. Application Data
(60) Provisional application No. 63/070,094, filed on Aug. 25, 2020.

(51) Int. Cl. H01L 33/56; H01L 25/075

(52) U.S. Cl. CPC H01L 33/56; H01L 25/0753

(57) ABSTRACT

A light source module includes a substrate, plural light-emitting elements and an encapsulation structure. The plural light-emitting elements are installed on the substrate. The encapsulation structure is installed on the substrate to cover the plural light-emitting elements. The encapsulation structure is made of a composition containing a polymeric glue material, a white powder material and a black powder material. In the composition, a content of the polymeric glue material is 65%˜99.8% by weight, a content of the white powder material is 0.1%˜20% by weight, and a content of the black powder material is 0.1%˜25% by weight.

### CROSS-REFERENCE TO RELATED APPLICATION

This application claims priority to U.S. Provisional Patent Application No. 63/070,094 filed Aug. 25, 2020, the contents of which are incorporated herein by reference.

### FIELD OF THE INVENTION

The present invention relates to a light source module, and more particularly to a light source module with high luminous efficiency.

### BACKGROUND OF THE INVENTION

Conventionally, a light source module is fabricated by using the following processes. Firstly, plural light-emitting diode dies are arranged in an array, and these light-emitting diode dies are fixed on a flexible printed circuit board (FPC), a printed circuit board (PCB) or a bismaleimide triazine (BT) resin substrate according to a surface-mount technology (SMT). Then, a required packaging glue (e.g., a transparent packaging glue or a fluorescent packaging glue) is filled in the spaces between these light-emitting diode dies. Alternatively, the packaging glue is filled in the region over the light-emitting diode dies through a full-surface compression molding process or a glue dispensing process. Consequently, the light-emitting diode dies are protected.

Regardless of which packaging method for the above light source module is used, the light-emitting diode dies are arranged in a high-density array to meet the requirements of delicate illumination. However, the light-emitting diode dies in the high-density array arrangement has an optically scattered problem. In addition, when these light-emitting diode dies are turned on simultaneously, a halo problem occurs because of the beam angles. Under this circumstance, the light beams generated by the light source module have poor purity.

As mentioned above, the light source module with the light-emitting diode dies in the high-density array arrangement has the halo problem. In order to solve the halo problem, a surface-roughened filter film, a filter film containing white filler or a metallic light guide plate is assembled with or attached on the top side of the light-emitting diode dies to cover the light-emitting diode dies. Consequently, the halo problem is reduced. Alternatively, a stopping wall made of white plastic material or black plastic material is formed on a plate, and the spaces for accommodating the light-emitting diode dies are retained. Then, the light-emitting diode dies are placed into the retained spaces. Since the adjacent light-emitting diode dies are separated from each other through the barrier material, the interference between the light-emitting diode dies is reduced.

As mentioned above, a secondary optical structure (e.g., a filter film or a stopping wall) is arranged along the optical path of the light source module to overcome the halo problem of the light source module. Consequently, the cost about the assembling process, the cost about the designing process and the cost about the environment protection measurement are largely increased. Moreover, the use of the secondary optical structure increases the overall thickness of the light source module. In other words, the arrangement of the secondary optical structure is detrimental to the slimness of the light source module.

Therefore, there is a need of providing an improved light source module in order to overcome the drawbacks of the conventional technologies.

### SUMMARY OF THE INVENTION

The present invention provides a light source module. The characteristics of different color power materials are utilized. Moreover, the different color power materials are mixed with the polymeric glue material in a specified weight ratio in order to produce the composition of an encapsulation structure. After the composition of the encapsulation structure is filled in the region over plural light-emitting elements in the high-density array, the composition of the light source module is fabricated. Due to the arrangement of the encapsulation structure, the halo problem of the light source module is effectively avoided.

The other objects and advantages of the present invention will be understood from the disclosed technical features.

In accordance with an embodiment of the present invention, a light source module is provided. The light source module includes a substrate, plural light-emitting elements and an encapsulation structure. The plural light-emitting elements are installed on the substrate. The encapsulation structure is installed on the substrate to cover the plural light-emitting elements. The encapsulation structure is made of a composition containing a polymeric glue material, a white powder material and a black powder material. In the composition, a content of the polymeric glue material is 65%˜99.8% by weight, a content of the white powder material is 0.1%˜20% by weight, and a content of the black powder material is 0.1%˜25% by weight.

In an embodiment, the polymeric glue material in the composition of the encapsulation structure includes silicone, epoxy resin or a hybrid material of silicone and epoxy resin.

In an embodiment, the white powder material in the composition of the encapsulation structure includes titanium dioxide, aluminum oxide or calcium carbonate.

In an embodiment, the black powder material in the composition of the encapsulation structure includes carbon black powder or boron nitride powder.

In an embodiment, the content of the polymeric glue material is 96.5% by weight, the content of the white powder material is 3% by weight, and the content of the black powder material is 0.5% by weight.

In an embodiment, a diameter of the black powder material is about 30 nm.

In accordance with another embodiment of the present invention, a light source module is provided. The light source module includes a substrate, plural light-emitting elements and at least one encapsulation structure. The plural light-emitting elements are installed on the substrate. The at least one encapsulation structure is installed on the substrate. Each of the at least one encapsulation structure is arranged between two adjacent light-emitting elements of the plural light-emitting elements. The encapsulation structure is made of a composition containing a polymeric glue material, a white powder material and a black powder material. In the composition, a content of the polymeric glue material is 65%˜99.8% by weight, a content of the white powder material is 0.1%˜20% by weight, and a content of the black powder material is 0.1%˜25% by weight.

In an embodiment, the encapsulation structure has a first height with respect to the substrate, and the light-emitting element has a second height with respect to the substrate. The first height is larger than or equal to the second height.

In an embodiment, the first height is larger than the second height, and a height difference between the first height and the second height is in a range between 0.01 mm and 0.3 mm.

From the above descriptions, the present invention provides the light source module. The characteristics of different color power materials are utilized. Moreover, the different color power materials are mixed with the polymeric glue material in a specified weight ratio in order to produce the composition of the encapsulation structure. After the composition of the encapsulation structure is filled in the region over the plural light-emitting elements in the high-density array, the composition of the light source module is fabricated. Due to the arrangement of the encapsulation structure, the halo problem of the light source module is effectively avoided, and the luminance of the light source module is effectively increased. Since the point light source is centralized in the light-outputting region, the characters or images can be displayed in high purity. Since it is not necessary to install an additional secondary optical structure along the optical path of the light source module, the cost about the assembling process, the cost about the designing process and the cost about the environment protection measurement are reduced. Moreover, since the light source module is not equipped with the additional secondary optical structure, the overall thickness of the light source module is reduced. Consequently, the light source module can meet the slimness requirement while achieving the waterproof, gas-barrier and insulation functions.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic cross-sectional view illustrating a light source module according to an embodiment of the present invention;

FIG. 2 schematically illustrates the comparisons between the halo phenomenon of the present light source module and the halo phenomenon of the conventional light source module;

FIG. 3 schematically illustrates the comparison between the luminance of the present light source module and the luminance of the conventional light source module; and

FIG. 4 is a schematic cross-sectional view illustrating a light source module according to another embodiment of the present invention.

### DETAILED DESCRIPTION OF THE PREFERRED EMBODIMENT

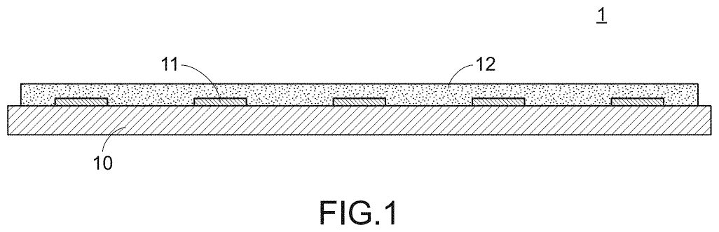

FIG. 1 is a schematic cross-sectional view illustrating a light source module according to an embodiment of the present invention. As shown in FIG. 1, the light source module 1 comprises a substrate 10, plural light-emitting elements 11 and an encapsulation structure 12. The plural light-emitting elements 11 are installed on the substrate 10. Preferably but not exclusively, the substrate 10 is a circuit board, and the light-emitting elements 11 are light-emitting diode dies. Each light-emitting diode die is electrically connected with the circuit board. By acquiring the current from the circuit board, the light-emitting diode dies are enabled to emit light beams. The encapsulation structure 12 is formed over the substrate 10 to cover the plural light-emitting elements 11. In an embodiment, the encapsulation structure 12 is made of a composition containing a polymeric glue material, a white powder material and a black powder material. In the composition, the content of the polymeric glue material is 65%˜99.8% by weight, the content of the white powder material is 0.1%˜20% by weight, and the content of the black powder material is 0.1%˜25% by weight. After the ingredients of the above composition are mixed, the composition of the encapsulation structure 12 is produced. After the composition is filled in the region over the plural light-emitting elements 11, the encapsulation structure 12 is formed over the substrate 10. Due to the encapsulation structure 12, the halo problem of the light source module 1 is largely eliminated.

In an embodiment, the light source module 1 is installed in an electronic device (not shown). Consequently, the electronic device has the function of outputting light beams. Generally, the light source modules are classified into two types. In the first type light source module, the circuit board has a circuitry for controlling the operation of the light-emitting elements 11, and the electronic function of the electronic device to process associated electronic signals is implemented by another circuit board. In the second type light source module, the circuit board has a circuitry for controlling the operation of the light-emitting elements 11, and the electronic function of the electronic device to process associated electronic signals is also implemented by the circuit board. For example, the light source module 1 is applied to a light-emitting diode display device, a backlight assembly of a TV, a lamp strip, a consumer e-sports display lamp, a wearable device indicator, or any other appropriate electronic device.

Preferably but not exclusively, the polymeric glue material in the composition of the encapsulation structure 12 includes silicone, epoxy resin, a hybrid material of silicone and epoxy resin, or any other appropriate hybrid material. For example, the white powder material in the composition of the encapsulation structure 12 includes titanium dioxide (TiO2), aluminum oxide (Al2O3) or calcium carbonate (CaCO3). It is noted that the type of the white powder material is not restricted. For example, the black powder material in the composition of the encapsulation structure 12 includes carbon black powder or boron nitride powder (BN). It is noted that the type of the black powder material is not restricted.

In an embodiment, the composition of the encapsulation structure 12 is produced by mixing 0.5% of carbon black powder, 3% of titanium dioxide and 96.5% of polymeric glue material. The diameter of the carbon black powder is about 30 nm. After the light-emitting elements 11 are arranged in a high-density array, the light-emitting elements 11 are packaged by the composition of the encapsulation structure 12. Consequently, the encapsulation structure 12 is formed as a natural barrier between these light-emitting elements 11. Moreover, since the carbon black powder can react with various free radicals to absorb portions of the weak light beams, the purpose of optimizing the halo phenomenon is achieved.

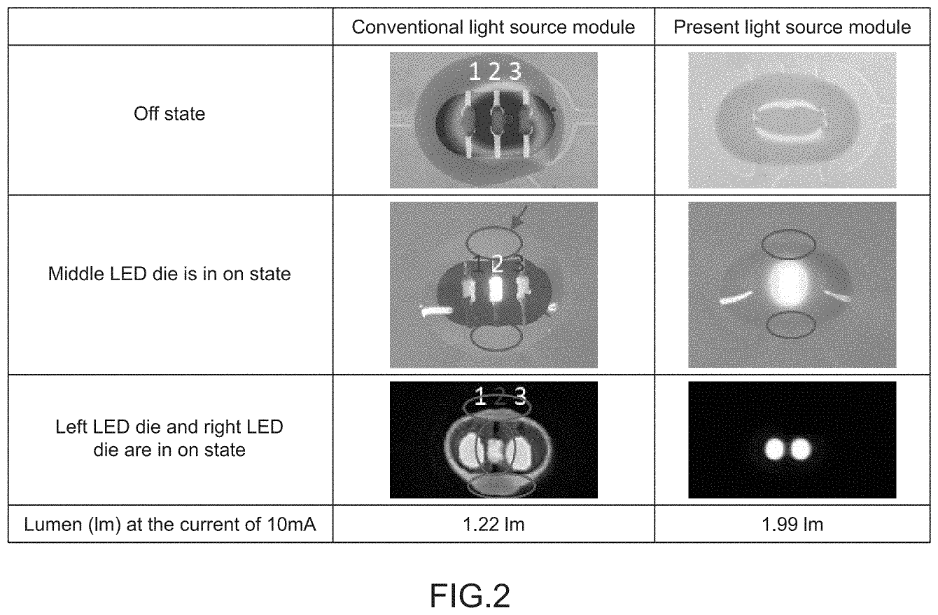

As mentioned above, the light source module 1 is equipped with the encapsulation structure 12 made of the special composition. After a series of experiments, the results are shown in FIG. 2.

FIG. 2 schematically illustrates the comparisons between the halo phenomenon of the present light source module and the halo phenomenon of the conventional light source module. As shown in FIG. 2, the light source module comprises three light-emitting diode dies in an array arrangement. When only the middle light-emitting diode die of the conventional light source module is turned on, the halo phenomenon generated by the turned-on light-emitting diode die influences the left light-emitting diode die and the right light-emitting diode die. Under this circumstance, the turned-off light-emitting diode dies emit the weak light beams. In the light source module of the present invention, the light-emitting diode dies are packaged by the encapsulation structure made of the special composition. When only the middle light-emitting diode die of the present light source module is turned on, the turned-on light-emitting diode die does not generate the halo phenomenon generated to influence the left light-emitting diode die and the right light-emitting diode die.

When the left light-emitting diode die and the right light-emitting diode die of the conventional light source module are turned on, the halo phenomenon generated by the turned-on light-emitting diode dies influences middle light-emitting diode die. Under this circumstance, the turned-off light-emitting diode die emits the weak light beams. In the light source module of the present invention, the light-emitting diode dies are packaged by the encapsulation structure made of the special composition. When the left light-emitting diode die and the right light-emitting diode die of the present light source module are turned on, the turned-on light-emitting diode dies do not generate the halo phenomenon generated to influence the middle light-emitting diode die.

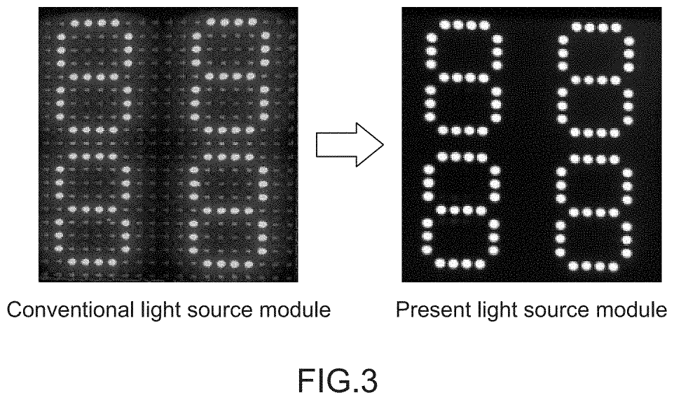

In case that the current is 10 mA, the lumen value of the conventional light source module is 1.22 lm, and the lumen value of the present light source module is increased from 1.22 lm to 1.99 lm. The comparison between the luminance of the conventional light source module and the luminance of the present light source module is shown in FIG. 3.

In another embodiment, the composition of the encapsulation structure 12 is produced by mixing 7.5% of carbon black powder, 1% of titanium dioxide and 91.5% of polymeric glue material. After the light-emitting diode dies are arranged in a high-density array, the light-emitting diode dies are packaged by the composition of the encapsulation structure 12. In case that the current is 10 mA, the luminance of the light source module 1 of the present invention is increased by 55% when compared with the conventional light source module containing no black powder material and no white powder material.

In the above embodiment, the composition of the encapsulation structure 12 is a mixture of the black powder material, the white powder material and the polymeric glue material in a specified weight ratio. It is noted that numerous modifications and alterations may be made while retaining the teachings of the invention. For example, in another embodiment, the composition of the encapsulation structure 12 is a mixture of the black powder material and the polymeric glue material. Alternatively, the composition of the encapsulation structure 12 is a mixture of the white powder material and the polymeric glue material.

For example, the composition of the encapsulation structure 12 is a mixture of the white powder material and the polymeric glue material, and the composition of the encapsulation structure 12 is produced by mixing 10% of titanium dioxide and 90% of polymeric glue material. After the light-emitting diode dies are arranged in a high-density array, the light-emitting diode dies are packaged by the composition of the encapsulation structure 12. In case that the current is 10 mA, the luminance of the light source module 1 of the present invention is increased by 111% when compared with the conventional light source module containing no white powder material.

In another embodiment, the white powder material with the content of 0.1%˜20% by weight and the black powder material with the content of 0.1%˜25% by weight are directly added to the composition for producing the light-emitting diode dies. Moreover, since the light-emitting diode dies made of this composition can react with various free radicals to absorb portions of the weak light beams, the purpose of optimizing the halo phenomenon is also achieved.

In another exemplary composition of the encapsulation structure, the content of the polymeric glue material is 75%˜99.8% by weight, the content of the white powder material is 0.1%˜20% by weight, and the content of the black powder material is 0.1%˜15% by weight. In a further exemplary composition of the encapsulation structure, the content of the polymeric glue material is 80%˜99.8% by weight, the content of the white powder material is 0.1%˜20% by weight, and the content of the black powder material is 0.1%˜10% by weight.

In accordance with a feature of the present invention, the characteristics of different color power materials (e.g., the black powder material and the white powder material) are utilized, and the different color power materials are mixed with the polymeric glue material in a specified weight ratio in order to produce the composition of the encapsulation structure 12. After the composition of the encapsulation structure 12 is filled in the region over the plural light-emitting elements 11, the composition of the encapsulation structure 12 is baked and solidified. Consequently, the light source module 1 is fabricated. Due to the arrangement of the encapsulation structure 12, the halo problem of the light source module 1 is effectively avoided, and the luminance of the light source module 1 is effectively increased.

Since it is not necessary to install an additional secondary optical structure along the optical path of the light source module 1, the cost about the assembling process, the cost about the designing process and the cost about the environment protection measurement are reduced. Moreover, since the light source module is not equipped with the additional secondary optical structure, the overall thickness of the light source module is reduced. Consequently, the light source module can meet the slimness requirement.

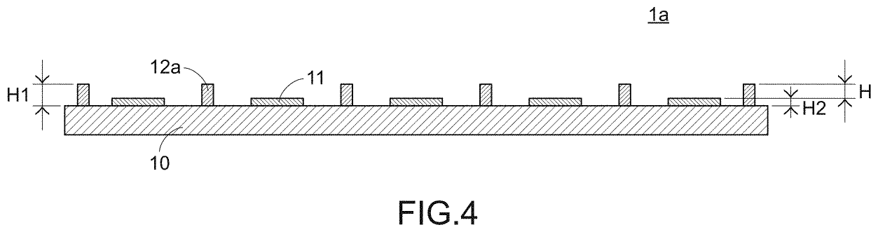

FIG. 4 is a schematic cross-sectional view illustrating a light source module according to another embodiment of the present invention. The components of the light source module 1a of this embodiment are similar to those of the light source module 1 as shown in FIG. 1. In comparison with the light source module 1, the light source module 1a of this embodiment comprises plural encapsulation structures 12a. Each encapsulation structure 12a is arranged between two adjacent 1 light-emitting elements 11. In other words, the encapsulation structures 12a are served as the stopping walls, and each light-emitting element 11 is accommodated within the space between the two adjacent encapsulation structure 12a.

Preferably but not exclusively, the composition of the encapsulation structure 12a is identical to the composition of the encapsulation structure 12. In the composition of the encapsulation structure 12a, the content of the polymeric glue material is 65%˜99.8% by weight, the content of the white powder material is 0.1%˜20% by weight, and the content of the black powder material is 0.1%˜25% by weight. Each encapsulation structure 12a is arranged between two adjacent 1 light-emitting elements 11. Due to the encapsulation structures 12a, the halo problem of the light source module 1a is largely eliminated.

In an embodiment, the encapsulation structure 12a has a first height H1 with respect to the substrate 10, and the light-emitting element 11 has a second height H2 with respect to the substrate 10. The first height H1 of the encapsulation structure 12a is larger than the second height H2 of the light-emitting element 11. Preferably, the height difference H between the first height H1 of the encapsulation structure 12a and the second height H2 of the light-emitting element 11 is in the range between 0.01 mm and 0.3 mm.

In the above embodiment, the first height H1 of the encapsulation structure 12a is larger than the second height H2 of the light-emitting element 11. It is noted that numerous modifications and alterations may be made while retaining the teachings of the invention. For example, in another embodiment, the first height H1 of the encapsulation structure 12a is equal to the second height H2 of the light-emitting element 11.

In an embodiment, the content of the black powder material (e.g., the carbon black powder) in the composition of the encapsulation structure 12a is negatively related to the first height H1 of the encapsulation structure 12a. That is, as the first height H1 of the encapsulation structure 12a is increased, the content of the black powder material in the composition of the encapsulation structure 12a is decreased. Whereas, as the first height H1 of the encapsulation structure 12a is decreased, the content of the black powder material in the composition of the encapsulation structure 12a is increased.

From the above descriptions, the present invention provides the light source module. The characteristics of different color power materials are utilized. Moreover, the different color power materials are mixed with the polymeric glue material in a specified weight ratio in order to produce the composition of the encapsulation structure. After the composition of the encapsulation structure is filled in the region over the plural light-emitting elements in the high-density array, the composition of the light source module is fabricated. Due to the arrangement of the encapsulation structure, the halo problem of the light source module is effectively avoided, and the luminance of the light source module is effectively increased. Since the point light source is centralized in the light-outputting region, the characters or images can be displayed in high purity. Since it is not necessary to install an additional secondary optical structure along the optical path of the light source module, the cost about the assembling process, the cost about the designing process and the cost about the environment protection measurement are reduced. Moreover, since the light source module is not equipped with the additional secondary optical structure, the overall thickness of the light source module is reduced. Consequently, the light source module can meet the slimness requirement while achieving the waterproof, gas-barrier and insulation functions.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

What is claimed is:

1. A light source module, comprising:
a substrate;
plural light-emitting elements installed on the substrate; and
an encapsulation structure installed on the substrate to cover the plural light-emitting elements, wherein the encapsulation structure is made of a composition containing a polymeric glue material, a white powder material and a black powder material, wherein in the composition, a content of the polymeric glue material is 65%˜99.8% by weight, a content of the white powder material is 0.1%˜20% by weight, and a content of the black powder material is 0.1%˜25% by weight.

2. The light source module according to claim 1, wherein the polymeric glue material in the composition of the encapsulation structure includes silicone, epoxy resin or a hybrid material of silicone and epoxy resin.

3. The light source module according to claim 1, wherein the white powder material in the composition of the encapsulation structure includes titanium dioxide, aluminum oxide or calcium carbonate.

4. The light source module according to claim 1, wherein the black powder material in the composition of the encapsulation structure includes carbon black powder or boron nitride powder.

5. The light source module according to claim 1, wherein in the composition, the content of the polymeric glue material is 96.5% by weight, the content of the white powder material is 3% by weight, and the content of the black powder material is 0.5% by weight.

6. The light source module according to claim 1, wherein a diameter of the black powder material is about 30 nm.

7. A light source module, comprising:
a substrate;
plural light-emitting elements installed on the substrate; and
at least one encapsulation structure installed on the substrate, wherein each of the at least one encapsulation structure is arranged between two adjacent light-emitting elements of the plural light-emitting elements, and the encapsulation structure is made of a composition containing a polymeric glue material, a white powder material and a black powder material, wherein in the composition, a content of the polymeric glue material is 65%˜99.8% by weight, a content of the white powder material is 0.1%˜20% by weight, and a content of the black powder material is 0.1%˜25% by weight.

8. The light source module according to claim 7, wherein the encapsulation structure has a first height with respect to the substrate, and the light-emitting element has a second height with respect to the substrate, wherein the first height is larger than or equal to the second height.

9. The light source module according to claim 8, wherein the first height is larger than the second height, and a height difference between the first height and the second height is in a range between 0.01 mm and 0.3 mm.
